(19) United States
(12) Patent Application Publication
(10) Pub. No.: US 2026/0314333 A1
(43) Pub. Date: Oct. 8, 2026

(54) CERAMIC HEATER

(71) Applicant: NGK INSULATORS, LTD., Nagoya-shi (JP)

(72) Inventors: Tomohiro HARA, Nagoya-shi (JP); Yohei KAJIURA, Nagoya-shi (JP); Naoki TSUZUKI, Nagoya-shi (JP); Keita IKEGAMI, Tokyo (JP)

(73) Assignee: NGK INSULATORS, LTD., Nagoya-shi (JP)

(21) Appl. No.: 19/576,225

(22) Filed: Mar. 24, 2026

Related U.S. Application Data
(63) Continuation of application No. PCT/JP2025/035893, filed on Oct. 9, 2025.

(30) Foreign Application Priority Data
Apr. 2, 2025 (JP) 2025-061092

(51) Int. Cl. H10P 72/76; H05B 3/18

(52) U.S. Cl. CPC H10P 72/7626; H05B 3/18; H10P 72/7616

(57) ABSTRACT

The ceramic heater includes: a plate; a resistance heating element built in the plate; and a shaft configured to support the plate. The shaft includes: a first end portion bonded to the plate and formed as a flange; a second end portion opposite the first end portion; a root portion extending from the first end portion between the first end portion and the second end portion; a main body portion connecting to the second end portion between the first end portion and the second end portion; and a connecting portion which connects the root portion and the main body portion. The main body portion has an inner diameter and an outer diameter being smaller than an inner diameter and an outer diameter of the root portion A thickness of at least a portion on the first end portion side in the root portion gradually increases toward the first end portion.

### CROSS-REFERENCE TO RELATED APPLICATIONS

This application claims priority from Japanese Patent Application No. 2025-061092, filed on Apr. 2, 2025, the contents of which are incorporated herein by reference in their entirety.

### TECHNICAL FIELD

The present disclosure relates to a ceramic heater with a shaft.

### BACKGROUND ART

In a semiconductor manufacturing apparatus, a ceramic heater is used to heat a wafer when, for example, processing such as film forming or etching is performed on the wafer. As the ceramic heater, there has been widely used a ceramic heater including: a disc-shaped plate including a heater layer built therein, the heater layer being formed from a resistance heating element that generates heat through energization; and a cylindrical shaft bonded to the plate (see, for example, Japanese Patent Application Laid-open No. 2012-080103.

### SUMMARY OF INVENTION

The ceramic heater is installed in a vacuum chamber of the semiconductor manufacturing apparatus. When processing such as film forming or etching processing is performed on a wafer, a temperature inside the vacuum chamber is elevated. For example, a second end portion of the shaft on a side opposite to a first end portion bonded to the plate is fixed to a support member with the presence of an O-ring therebetween. Sealability of the O-ring decreases in a high-temperature environment inside the vacuum chamber. Thus, in order to maintain the sealability of the O-ring, the second end portion of the shaft is cooled. As a result, a temperature difference is generated between the first end portion bonded to the plate being heated and the second end portion being cooled, and a temperature in the shaft between its two end portions changes in an axial direction thereof.

Along with this change in temperature, thermal stress is generated in the shaft. A portion of the shaft, which is close to the first end portion, has an elevated temperature. Thus, a thermal conductivity is decreased therein, resulting in a large temperature gradient. Due to the large temperature gradient, large thermal stress is generated in the above-mentioned portion, with the result that damage such as a crack may occur therein. In particular, when a shaft having a low thermal conductivity is used for the ceramic heater, the above-mentioned problem becomes more pronounced.

The present disclosure has one object to provide a ceramic heater capable of suppressing damage in a portion of a shaft, which is close to a first end portion bonded to a plate, due to thermal stress.

According to one aspect of the present disclosure, there is provided a ceramic heater, including: a plate including: a first principal surface configured to support a wafer; and a second principal surface positioned across a gap from the first principal surface in a thickness direction of the plate; a resistance heating element which is built in the plate, and which is configured to generate heat through energization; and a shaft having a tubular shape which is configured to support the plate on the second principal surface side. In the ceramic heater, the shaft includes: a first end portion which is an end portion on a side bonded to the second principal surface of the plate, and which is formed as a flange; a second end portion which is an end portion on a side opposite to the first end portion in an axial direction of the shaft; a root portion which is continuous from the first end portion between the first end portion and the second end portion; a main body portion which is continuous with the second end portion between the first end portion and the second end portion, and which has an inner diameter and an outer diameter being smaller than an inner diameter and an outer diameter of the root portion; and a connecting portion which connects the root portion and the main body portion to each other. Further, a thickness of at least a portion on the first end portion side in the root portion gradually increases toward the first end portion.

According to another aspect of the present disclosure, there is also provided a ceramic heater, including: a plate including: a first principal surface configured to support a wafer; and a second principal surface positioned across a gap from the first principal surface in a thickness direction of the plate; a resistance heating element which is built in the plate, and which is configured to generate heat through energization; and a shaft having a tubular shape which is configured to support the plate on the second principal surface side. In the ceramic heater, the shaft includes: a first end portion which is an end portion on a side bonded to the second principal surface of the plate, and which is formed as a flange; a second end portion which is an end portion on a side opposite to the first end portion in an axial direction of the shaft; a main body portion which is continuous with the second end portion between the first end portion and the second end portion; and a root portion which is continuous from the first end portion between the first end portion and the second end portion, and which connects the first end portion and the main body portion to each other. Further, a thickness of the root portion gradually increases toward the first end portion, and an outer peripheral surface of the root portion is a curved surface being curved away from an inner peripheral surface of the root portion as the root portion extends toward the first end portion, and a curvature radius of the curved surface gradually decreases toward the first end portion.

According to still another aspect of the present disclosure, there is also provided a ceramic heater, including: a plate including: a first principal surface configured to support a wafer; and a second principal surface positioned across a gap from the first principal surface in a thickness direction of the plate; a resistance heating element which is built in the plate, and which is configured to generate heat through energization; and a shaft having a tubular shape which is configured to support the plate on the second principal surface side. In the ceramic heater, the shaft includes: a first end portion which is an end portion on a side bonded to the second principal surface of the plate, and which is formed as a flange; a second end portion which is an end portion on a side opposite to the first end portion in an axial direction of the shaft; a root portion which is continuous from the first end portion between the first end portion and the second end portion, and which is allowed to have a high temperature equal to or higher than 400°C when the plate is heated to 650°C and the second end portion is cooled to 35°C; and a main body portion which is continuous with the second end portion between the first end portion and the second end portion, and which is allowed to have a temperature lower than 400°C when the plate is heated to 650°C and the second end portion is cooled to 35°C. Further, a thickness of at least a portion on the first end portion side in the root portion gradually increases toward the first end portion.

With the ceramic heater according to the present disclosure, thermal stress generated in the root portion of the shaft, which is a portion close to the first end portion bonded to the plate, can be reduced. Thus, damage in the root portion of the shaft due to thermal stress can be suppressed.

### BRIEF DESCRIPTION OF DRAWINGS

FIG. 1 is a longitudinal sectional view of a ceramic heater according to a first embodiment of the present disclosure.

FIG. 2 is a partially enlarged longitudinal sectional view of a shaft used for the ceramic heater illustrated in FIG. 1.

FIG. 3 is a longitudinal sectional view of a ceramic heater according to a second embodiment of the present disclosure.

FIG. 4 is a partially enlarged longitudinal sectional view of a shaft used for the ceramic heater illustrated in FIG. 3.

FIG. 5 is a partially enlarged longitudinal sectional view of a shaft of a comparative example.

FIG. 6 is a partially enlarged longitudinal sectional view of a shaft of a comparative example.

### DESCRIPTION OF EMBODIMENTS

### Outline of Embodiments

First, aspects of carrying out a ceramic heater according to the present disclosure are listed and described.

A ceramic heater according to a first aspect of the present disclosure includes: a plate including: a first principal surface that supports a wafer; and a second principal surface positioned across a gap from the first principal surface in a thickness direction of the plate; a resistance heating element which is built in the plate, and which generates heat through energization; and a shaft having a tubular shape which supports the plate on the second principal surface side. In the ceramic heater according to the first aspect, the shaft includes: a first end portion which is an end portion on a side bonded to the second principal surface of the plate, and which is formed as a flange; a second end portion which is an end portion on a side opposite to the first end portion in an axial direction of the shaft; a root portion which is continuous from the first end portion between the first end portion and the second end portion; a main body portion which is continuous with the second end portion between the first end portion and the second end portion, and which has an inner diameter and an outer diameter being smaller than an inner diameter and an outer diameter of the root portion; and a connecting portion which connects the root portion and the main body portion to each other. Further, a thickness of at least a portion on the first end portion side in the root portion gradually increases toward the first end portion.

When the plate is heated with the resistance heating element, the root portion of the shaft, which is close to the first end portion bonded to the shaft, has an elevated temperature. Thus, a thermal conductivity thereof decreases. Meanwhile, when the shaft has a large thickness at the root portion, heat is easily conducted through the root portion. Accordingly, when the thickness of the root portion gradually increases toward the first end portion having a high temperature as in the ceramic heater according to the first aspect, the thermal conductivity of the root portion also gradually increases toward the first end portion. As a result, a temperature gradient in the root portion decreases, reducing thermal stress generated in the root portion. As described above, the ceramic heater according to the first aspect can suppress damage in the root portion of the shaft due to thermal stress.

As a ceramic heater according to a second aspect of the present disclosure, the ceramic heater according to the above-mentioned first aspect may be configured such that a thickness of the main body portion is uniform over an entire length of the main body portion, and is smaller than a thickness of the root portion at a boundary position between the root portion and the connecting portion. In the ceramic heater according to the second aspect, the thickness of the main body portion of the shaft is uniformly small over the entire length of the main body portion. Thus, stiffness of the main body portion decreases, mitigating thermal stress generated in the main body portion. As a result, damage in the main body portion of the shaft due to thermal stress can be suppressed.

As a ceramic heater according to a third aspect of the present disclosure, the ceramic heater according to the above-mentioned second aspect may be configured such that a thickness of at least a portion on the root portion side in the connecting portion gradually increases toward the root portion. In the ceramic heater according to the third aspect, when the thickness of the portion of the connecting portion of the shaft on the root portion side gradually increases toward the root portion having a high temperature, a thermal conductivity of the portion gradually increases toward the root portion. Thus, a temperature gradient in the portion can be reduced. Accordingly, thermal stress can be reduced in an area from the connecting portion to the root portion of the shaft. As a result, damage in the area from the connecting portion to the root portion due to thermal stress can be suppressed.

As a ceramic heater according to a fourth aspect of the present disclosure, the ceramic heater according to any one of the above-mentioned first aspect to third aspect may be configured such that an inner peripheral surface of the root portion is perpendicular to the second principal surface of the plate. In the ceramic heater according to the fourth aspect, a thickness of the root portion can be significantly increased toward the first end portion. Thus, thermal stress generated in the root portion of the shaft can be effectively reduced.

A ceramic heater according to a fifth aspect of the present disclosure includes: a plate including: a first principal surface that supports a wafer; and a second principal surface positioned across a gap from the first principal surface in a thickness direction of the plate; a resistance heating element which is built in the plate, and which generates heat through energization; and a shaft having a tubular shape which supports the plate on the second principal surface side. In the ceramic heater according to the fifth aspect, the shaft includes: a first end portion which is an end portion on a side bonded to the second principal surface of the plate, and which is formed as a flange; a second end portion which is an end portion on a side opposite to the first end portion in an axial direction of the shaft; a main body portion which is continuous with the second end portion between the first end portion and the second end portion; and a root portion which is continuous from the first end portion between the first end portion and the second end portion, and which connects the first end portion and the main body portion to each other. Further, a thickness of the root portion gradually increases toward the first end portion, and an outer peripheral surface of the root portion is a curved surface being curved away from an inner peripheral surface of the root portion as the root portion extends toward the first end portion, and a curvature radius of the curved surface gradually decreases toward the first end portion.

When the thickness of the root portion gradually increases toward the first end portion having a high temperature as in the ceramic heater according to the fifth aspect, the thermal conductivity of the root portion also gradually increases toward the first end portion. Thus, a temperature gradient in the root portion decreases, reducing thermal stress generated in the root portion. When the thickness of the root portion more significantly increases toward the first end portion, the thermal conductivity of the root portion also more significantly increases toward the first end portion. Thus, the temperature gradient in the root portion can be further reduced, and hence the thermal stress generated in the root portion can be effectively reduced. As described above, the ceramic heater according to the fifth aspect can suppress damage in the root portion of the shaft due to thermal stress.

As a ceramic heater according to a sixth aspect of the present disclosure, the ceramic heater according to the above-mentioned fifth aspect may be configured such that a thickness of the main body portion is uniform over an entire length of the main body portion. In the ceramic heater according to the sixth aspect, the thickness of the main body portion of the shaft is uniformly small over the entire length of the main body portion. Thus, stiffness of the main body portion decreases, mitigating thermal stress generated in the main body portion. As a result, damage in the main body portion of the shaft due to thermal stress can be suppressed.

As a ceramic heater according to a seventh aspect of the present disclosure, the ceramic heater according to the above-mentioned fifth aspect or sixth aspect may be configured such that an inner peripheral surface of the root portion is perpendicular to the second principal surface of the plate. In the ceramic heater according to the seventh aspect, the thickness of the root portion can be significantly increased toward the first end portion. Thus, thermal stress generated in the root portion of the shaft can be effectively reduced.

A ceramic heater according to an eighth aspect of the present disclosure includes: a plate including: a first principal surface that supports a wafer; and a second principal surface positioned across a gap from the first principal surface in a thickness direction of the plate; a resistance heating element which is built in the plate, and which generates heat through energization; and a shaft having a tubular shape which supports the plate on the second principal surface side. In the ceramic heater according to the eighth aspect, the shaft includes: a first end portion which is an end portion on a side bonded to the second principal surface of the plate, and which is formed as a flange; a second end portion which is an end portion on a side opposite to the first end portion in an axial direction of the shaft; a root portion which is continuous from the first end portion between the first end portion and the second end portion, and which is allowed to have a high temperature equal to or higher than 400°C when the plate is heated to 650°C and the second end portion is cooled to 35°C; and a main body portion which is continuous with the second end portion between the first end portion and the second end portion, and which is allowed to have a temperature lower than 400°C when the plate is heated to 650°C and the second end portion is cooled to 35°C. Further, a thickness of at least a portion on the first end portion side in the root portion gradually increases toward the first end portion.

In the ceramic heater according to the eighth aspect, regarding the root portion having an elevated temperature when the plate is heated, the thickness of at least the portion on the first end portion side gradually increases toward the first end portion. As a result, heat is easily conducted through the root portion, and the thermal conductivity of the root portion gradually increases toward the first end portion having a high temperature. In this manner, the temperature gradient in the root portion can be reduced, and hence the thermal stress generated in the root portion can be reduced. Thus, the ceramic heater according to the eighth aspect can suppress damage in the root portion of the shaft due to thermal stress.

As a ceramic heater according to a ninth aspect of the present disclosure, the ceramic heater according to any one of the above-mentioned first aspect to eighth aspect may be configured such that a ratio of a thickness of the root portion at an end on the first end portion side to a thickness of the root portion at an end on the main body portion side is 2.0 or more and 10.0 or less. The ceramic heater according to the ninth aspect can ensure bond strength of the shaft and the plate while desirably mitigating the thermal stress generated in the root portion.

As a ceramic heater according to a tenth aspect of the present disclosure, the ceramic heater according to any one of the above-mentioned first aspect to ninth aspect may be configured such that the shaft is formed of a material containing Mg and Al. When the shaft has a high thermal conductivity, heat of the plate is easily transferred to the shaft. Thus, thermal uniformity of the plate is affected, and, in addition, power consumption increases for heating the plate. Accordingly, it is desired that a shaft with a low thermal conductivity formed of a material containing Mg and Al, such as MgAlON or MgAl₂O₄, be used. Meanwhile, in the shaft with a low thermal conductivity, larger thermal stress is generated in the root portion when the plate is heated. In the ceramic heater according to the tenth aspect, however, thermal stress generated in the root portion can be reduced. Thus, the shaft with a low thermal conductivity formed of a material containing Mg and Al can be suitably used.

### SPECIFIC EXAMPLES OF EMBODIMENTS

Next, embodiments of the ceramic heater according to the present disclosure are described with reference to the drawings. Throughout the drawings, parts that are the same as, or correspond to, each other are denoted by the same reference numeral, and description thereof is not repeated.

### First Embodiment

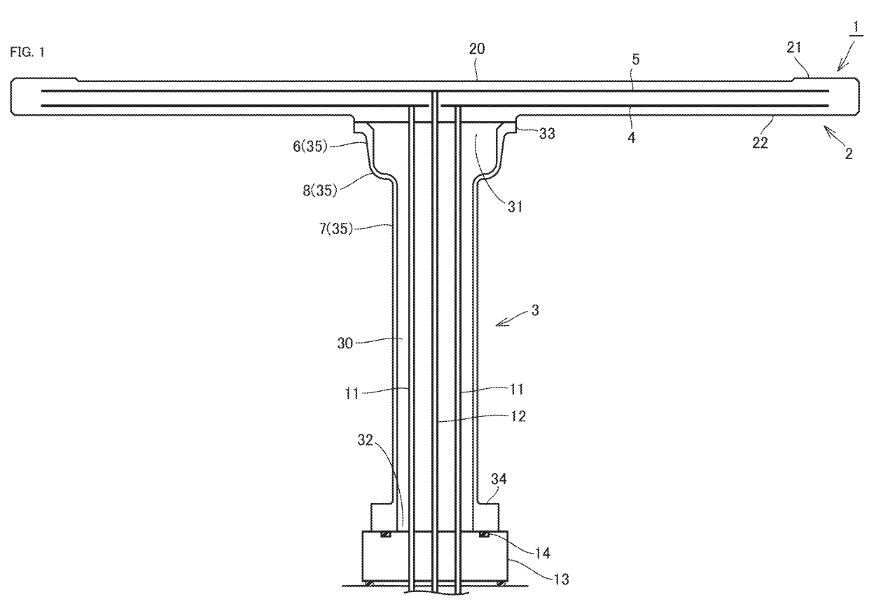

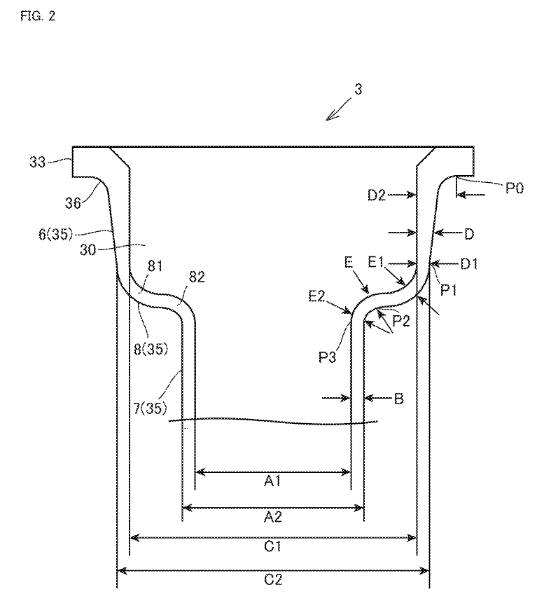

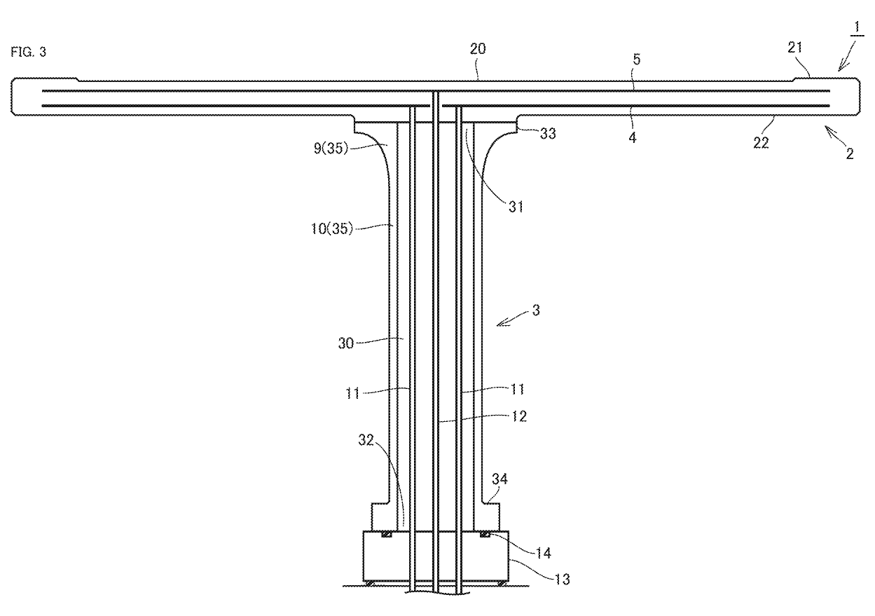

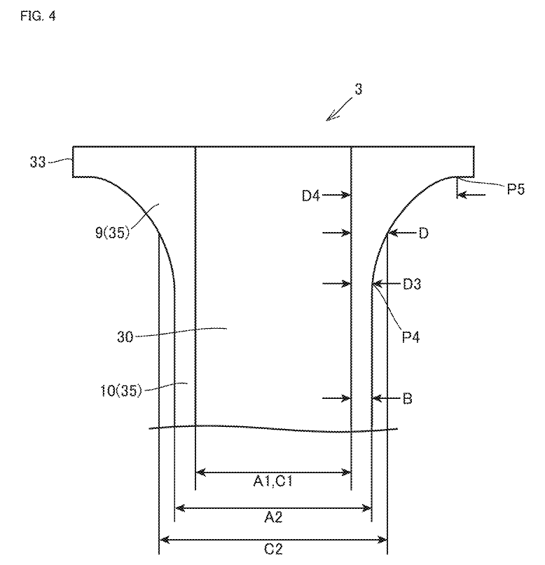

FIG. 1 is a longitudinal sectional view of a ceramic heater 1 according to a first embodiment. FIG. 2 is a partially enlarged longitudinal sectional view of a shaft 3 used for the ceramic heater 1 illustrated in FIG. 1. FIG. 3 is a longitudinal sectional view of a ceramic heater 1 according to a second embodiment. FIG. 4 is a partially enlarged longitudinal sectional view of a shaft 3 used for the ceramic heater 1 illustrated in FIG. 3. In FIGS. 1 to 4, schematic structures are illustrated.

In the following description, viewing an object in a thickness direction of a plate 2 is referred to as "plan view." Further, a shape of the object in the thickness direction of the plate 2 is referred to as "shape in plan view."

The ceramic heater 1 is installed as a stage made of ceramic for supporting a wafer, in a vacuum chamber of a semiconductor manufacturing apparatus. An interior of the vacuum chamber is set to a vacuum atmosphere or a reduced-pressure atmosphere. For example, film forming processing in which a thin film is formed on the wafer by chemical vapor deposition (CVD) or physical vapor deposition (PVD), or processing of etching the wafer is executed inside the vacuum chamber.

The ceramic heater 1 has a heater function for heating the wafer so that a temperature of the wafer is set to a desired temperature when the film forming processing, the etching processing, or the like is performed on the wafer in the semiconductor manufacturing apparatus. Further, the ceramic heater 1 may have an electrostatic chucking function for chucking the wafer to the plate 2 or a plasma generating function for generating plasma between the ceramic heater 1 and an upper electrode set on a ceiling inside the vacuum chamber.

Reference is made to FIGS. 1 and 3. The ceramic heater 1 includes: the plate 2 made of ceramic with a sheet-like shape; the shaft 3 made of ceramic with a tubular shape; and a heater layer 4 built in the plate 2. The plate 2 and the shaft 3 are integrated with each other by bonding the shaft 3 to the plate b through, for example, diffusion bonding or solid-phase bonding. A method of bonding the plate 2 and the shaft 3 is not limited to the above-mentioned examples.

A plurality of first power feeding members 11 made of metal, each having, for example, a rod-like shape, are electrically connected to the heater layer 4 through intermediation of power feeding terminals. When energized from an external DC power source via the first power feeding members 11, the heater layer 4 generates heat to heat the plate 2.

Electrodes 5 which are at least one of radio-frequency electrodes (RF electrodes) or electrostatic chuck electrodes (ESC electrodes) or electrodes 5 functioning as any of the RF electrodes or the ESC electrodes may be further provided inside the plate 2. The RF electrode is an electrode for generating plasma between the electrode and an upper electrode installed on a ceiling inside the vacuum chamber by a radio-frequency voltage being applied to the electrode. The ESC electrode is an electrode for chucking the wafer supported by the plate 2 through electroadhesion by a voltage being applied to the electrode.

It is preferred that the electrodes 5 be arranged on a first principal surface 21 side with respect to the heater layer 4 in the thickness direction of the plate 2. A second power feeding member 12 made of metal having, for example, a rod-like shape, is electrically connected to the electrode 5 through intermediation of a power feeding terminal. Radio-frequency power is fed to the electrode 5, for example, from an external radio-frequency power source via the second power feeding member 12, and/or a DC voltage is applied to the electrode 5 from a DC power source.

The first power feeding members 11 and the second power feeding member 12 are inserted from a second principal surface 22 into the plate 2 in the vicinity of a center of the plate 2 in plan view. As a result, the first power feeding members 11 are electrically connected to the heater layer 4, and the second power feeding member 12 is electrically connected to the electrode 5.

### Description of Plate

The plate 2 contains, as a main component, for example, aluminum nitride (AlN), aluminum oxide (Al₂O₃), silicon carbide (SiC), or silicon nitride (Si₃N₄). The plate 2 is preferred to be made of aluminum nitride containing, as a main component, aluminum nitride high in thermal conductivity. The term "main component" means a component having the highest content among contained components, and the content of the main component is, for example, 50% or higher by mass, preferably 70% or higher by mass, and more preferably 90% or higher by mass.

The plate 2 may contain other components such as a component originating from a sintering aid, as long as the above-mentioned material is contained as the main component. A rare-earth metal oxide is given as an example of the sintering aid. The plate 2 is formed from, for example, a sintered ceramic body obtained by baking ceramic powder, but may be formed by other methods, for example, may be formed from a laminate obtained by kneading a mixture of ceramic powder and a binder into a sheet form, layering a plurality of thus obtained green sheets, and firing the layered green sheets.

Reference is made to FIGS. 1 and 3. The plate 2 includes the first principal surface 21 and the second principal surface 22 which are a pair of principal surfaces positioned across a gap from each other in the thickness direction. The first principal surface 21 and the second principal surface 22 are parallel, or substantially parallel, to each other. The phrase "substantially parallel" includes a case in which one is tilted with respect to the other to a certain degree within tolerance, a case in which at least one is somewhat warped and is not flat, and the like. In the present disclosure, the first principal surface 21 side is defined as an upper side, and the second principal surface 22 side is defined as a lower side, in the thickness direction of the plate 2.

A circular shape is given as an example of the shape of the plate 2 in plan view, but the shape is not limited to a circular shape. The circular shape is not always required to be a complete circle, and may be an incomplete circle missing a part, such as orientation flat. A diameter of the plate 2 may be appropriately determined in accordance with a diameter of the wafer supported by the plate 2. The diameter of the plate 2 is, for example, 200 mm or more and 400 mm or less. A thickness of the plate 2 is, for example, 5 mm or more and 30 mm or less.

The first principal surface 21 of the plate 2 includes a wafer supporting region 20 for supporting a wafer. The first principal surface 21 may be formed so that an entire area thereof is the wafer supporting region 20. Alternatively, the first principal surface 21 may be formed so that an outer peripheral wall rising over an entire circumference of the plate 2 in its circumferential direction is formed on a region extending inward from an outer peripheral edge of the first principal surface 21 and having a predetermined width and a region inside the outer peripheral wall serves as the wafer supporting region 20. When the outer peripheral wall to surround the wafer is formed around the wafer supporting region 20, the wafer is supported on the first principal surface 21 under a state in which positional misalignment thereof is suppressed.

A ring-shaped protrusion called a seal band may be formed on the wafer supporting region 20 of the first principal surface 21. An annular shape is given as an example of a shape of the ring-shaped protrusion in plan view, but the shape is not limited to an annular shape. With the wafer being placed on the ring-shaped protrusion, a space surrounded by the ring-shaped protrusion is defined between the wafer and the plate 2. Supplying a gas with high thermal conductivity, for example, a helium gas enables efficient thermal conduction between the wafer and the plate 2.

For example, a plurality of columnar or truncated conical small protrusions may be provided in the wafer supporting region 20 of the first principal surface 21. The plurality of small protrusions are, for example, provided in a region of the wafer supporting region 20 that is surrounded by the ring-shaped protrusion at intervals equal to one another. A height of each of the small protrusions is the same, or substantially the same, as the height of the ring-shaped protrusion. With the wafer being placed not only on the ring-shaped protrusion but also on the plurality of small protrusions, entirety of the wafer is supported evenly.

Various holes may be formed in the plate 2 so as to pass therethrough in the thickness direction of the plate 2. For example, a hole for inserting a lift pin which is used to lift up the wafer from the plate 2 after processing such as film forming on the wafer is finished may be formed in the plate 2. Further, a hole for supplying gas into the space surrounded by the ring-shaped protrusion between the wafer and the plate 2 may be formed in the plate 2. Further, a hole for inserting a thermocouple that detects a temperature of the plate 2 may be formed in the plate 2.

### Description of Heater Layer

Reference is made to FIGS. 1 and 3. The heater layer 4 spreads in a planar pattern inside the plate 2, along an imaginary plane parallel or substantially parallel to the first principal surface 21. The heater layer 4 is formed from a resistance heating element containing, as a main component, a conductive material such as a high melting point metal, an alloy of a high melting point metal, or a carbide of a high melting point metal. Molybdenum (Mo), tungsten (W), and niobium (Nb) are given as examples of the high melting point metal.

The resistance heating element is formed from, for example, a thin plate, or a thin plate with many small through-holes opened therein such as a perforated plate, a mesh, or a film formed by printing conductive paste. Alternatively, the resistance heating element is formed from, for example, conductive paste, a coil, or a meandering element wire which is provided in a predetermined pattern with a single continuous line for a wiring.

The plate 2 may be divided into a plurality of zones in plan view so that the heater layer 4 is formed for each of the zones. For example, the heater layer 4 may be formed on each of a plurality of zones obtained by equiangularly dividing the plate 2 in plan view. Alternatively, the heater layer 4 having a circular shape in plan view may be formed in an inner zone which is a region within a first distance from the center of the plate 2 in plan view, and the heater layer 4 having an annular shape in plan view may be formed in an outer zone which is a ring-shaped region within a second distance (>the first distance) from the center of the plate 2 and which is on an outer side of the inner zone. The heater layer 4 in the inner zone and the heater layer 4 in the outer zone may be arranged at the same position or different positions in an up-and-down direction inside the plate 2.

When a plurality of heater layers 4 are built in the plate 2, a pair of first power feeding members 11 are electrically connected to each of the heater layers 4. The first power feeding members 11 may be connected directly to the heater layer 4 or indirectly thereto through intermediation of a jumper or the like.

### Description of Shaft

The shaft 3 contains, as a main component, aluminum nitride (AlN), aluminum oxide (Al₂O₃), silicon carbide (SiC), silicon nitride (Si₃N₄), MgAlON, spinel (MgAl₂O₄), or the like. It is preferred that the shaft 3 have a low thermal conductivity and be made of a material containing Mg and Al, such as MgAlON or spinel. The term "main component" means a component having the highest content among contained components, and the content of the main component is, for example, 50% or higher by mass, preferably 70% or higher by mass, and more preferably 90% or higher by mass.

The shaft 3 may contain other components such as a component originating from a sintering aid, as long as the above-mentioned material is contained as the main component. A rare-earth metal oxide is given as an example of the sintering aid. The shaft 3 is formed from, for example, a sintered ceramic body obtained by baking ceramic powder. The shaft 3 may be formed by other methods, for example, may be formed from a laminate obtained by kneading a mixture of ceramic powder and a binder into a sheet form, layering a plurality of thus obtained green sheets, and firing the layered green sheets.

The shaft 3 may be formed from a sintered body made of the same material as the material for the plate 2, or may be formed from a sintered body made of a material different from the material for the plate 2.

Reference is made to FIGS. 1 and 3. The shaft 3 has a first opening 31 and a second opening 32 which are a pair of openings positioned at both ends in an axial direction of the shaft 3. The shaft 3 supports the plate 2 on the second principal surface 22 side. A shape of a cross section of the shaft 3 taken along a plane orthogonal to the axial direction (hereinafter referred to as "transverse cross section") is, for example, a circular shape, but is not limited to the circular shape. The shaft 3 is arranged so as to be concentric with the plate 2. A diameter of the shaft 3 is smaller than the diameter of the plate 2.

The shaft 3 includes: a first end portion 33 which is an end portion surrounding the first opening 31; a second end portion 34 which is an end portion surrounding the second opening 32; and a shaft portion 35 which is a portion between the first end portion 33 and the second end portion 34.

The first end portion 33 of the shaft 3 is formed as a flange projecting outward in a radial direction of the shaft 3. The first end portion 33 is bonded to the second principal surface 22 of the plate 2. In a cross section of the shaft 3 taken along a plane parallel to the axial direction (hereinafter referred to as "longitudinal cross section"), an inner peripheral surface of the first end portion 33 may be inclined outward in at least a portion on the second principal surface 22 side as the first end portion 33 extends upward (see FIG. 1) or may extend upward in a straight manner to be orthogonal to the second principal surface 22 of the plate 2 (see FIG. 3). In the shaft 3 illustrated in FIG. 1, the inner peripheral surface of the first end portion 33 may be curved so that at least a portion thereof on the second principal surface 22 side expands outward as the first end portion 33 extends upward.

The second end portion 34 of the shaft 3 is an end portion on a side opposite to the first end portion 33 in the axial direction. It is preferred that the second end portion 34 be formed as a flange, although the second end portion 34 is not limited to a particular shape. The second end portion 34 is connected to, for example, a support member 13 with the presence of an O-ring 14 therebetween. As a result, an internal space 30 of the shaft 3 is isolated from a space inside the vacuum chamber of the semiconductor manufacturing apparatus, which is an external space.

Besides the first power feeding members 11 connected to the heater layer 4 and the second power feeding member 12 connected to the electrode 5, a thermocouple for measuring a temperature of the plate 2, and the like are housed in the internal space 30 of the shaft 3. As a result, the above-mentioned members are isolated from the space inside the vacuum chamber of the semiconductor manufacturing apparatus, which is an external space. Thus, the above-mentioned members can be prevented from being exposed to plasma or the like.

The shaft portion 35 of the shaft 3 is formed so that its thickness is not uniform over an entire length thereof, and is varied for each portion. The ceramic heater 1 is installed in the vacuum chamber of the semiconductor manufacturing apparatus. When processing such as film forming or etching processing is performed on the wafer, a temperature inside the vacuum chamber is elevated. The second end portion 34 of the shaft 3 on the side opposite to the first end portion 33 bonded to the plate 2 is fixed to the support member 13 with the presence of the O-ring 14 therebetween. Sealability of the O-ring 14 decreases in a high-temperature environment inside the vacuum chamber. Thus, in order to maintain the sealability of the O-ring 14, the second end portion 34 of the shaft 3 is cooled. Accordingly, a large temperature difference is generated in the shaft 3 between the first end portion 33 which is bonded to the plate 2 heated with the heater layer 4 and the second end portion 34 which is cooled, and a temperature of the shaft portion 35 varies in the axial direction between the end portions 33 and 34. Along with this change in temperature, thermal stress is generated in the shaft 3. Damage such as a crack may occur in the shaft 3 due to thermal stress. Thus, in this embodiment, damage in the shaft 3 due to thermal stress is suppressed by varying the thickness of the shaft portion 35 of the shaft 3 for each portion. The setting of thicknesses and dimensions is specifically described below.

### Description of Shaft Portion of Shaft in First Embodiment

Reference is made to FIGS. 1 and 2. The shaft portion 35 of the shaft 3 in the first embodiment includes a root portion 6, a main body portion 7, and a connecting portion 8. The root portion 6 is continuous from the first end portion 33. The main body portion 7 is continuous with the second end portion 34. The connecting portion 8 connects the root portion 6 and the main body portion 7 to each other.

The main body portion 7 is a portion of the shaft portion 35 of the shaft 3, and extends upward by a predetermined length from the second end portion 34 which is a lower end portion of the shaft 3. Further, the main body portion 7 is the longest and narrowest portion in the shaft portion 35 of the shaft 3, and is a small wall thickness portion with the smallest thickness (length from an inner peripheral surface to an outer peripheral surface thereof).

The main body portion 7 is formed so that an inner diameter A1 and an outer diameter A2 are constant (the inner diameter A1 and the outer diameter A2 do not change in the axial direction of the shaft 3). That is, the main body portion 7 is formed so as to have a thickness B being uniform over its entire length and to extend upward in a straight manner.

The main body portion 7 may be formed with the thickness B being uniform over its entire length so as to be inclined outward as the main body portion 7 extends upward. Alternatively, the main body portion 7 may be formed with the thickness B being uniform over its entire length and may be bent while extending upward so that a portion on the root portion 6 side is inclined outward as the main body portion 7 extends upward.

With the thickness B of the main body portion 7 being uniformly small over the entire length of the main body portion 7, stiffness of the main body portion 7 decreases, mitigating thermal stress generated in the main body portion 7. As a result, damage in the main body portion 7 due to thermal stress can be suppressed. The thickness B of the main body portion 7 is not always required to be uniform over the entire length of the main body portion 7.

In terms of enabling desirable mitigation of thermal stress generated in the main body portion 7, it is preferred that the thickness B of the main body portion 7 be 3.0 mm or less. Further, in terms of ensuring of strength of the main body portion 7, it is preferred that the thickness B of the main body portion 7 be 2.0 mm or more.

The root portion 6 extends downward by a predetermined length from the first end portion 33, which is a joint portion of the shaft portion 35 of the shaft 3 with the plate 2, and is close to the first end portion 33. An inner diameter C1 and an outer diameter C2 of the root portion 6 are larger than the inner diameter A1 and the outer diameter A2 of the main body portion 7. Further, a length of the root portion 6 is smaller than a length of the main body portion 7. Further, a thickness D of the root portion 6 is larger than the thickness B of the main body portion 7. The root portion 6 is a large wall thickness portion in the shaft portion 35 of the shaft 3.

The root portion 6 is formed so that the thickness D gradually increases as the root portion 6 extends upward at least in a portion thereof on the first end portion 33 side. In this embodiment, the root portion 6 is formed so that the thickness D gradually increases in its entirety as the root portion 6 extends upward.

The root portion 6 is formed with the inner diameter C1 being constant and the outer diameter C2 gradually increasing as the root portion 6 extends upward so that the thickness D gradually increases. That is, an inner peripheral surface of the root portion 6 extends upward in a straight manner and is perpendicular to the second principal surface 22 of the plate 2. An outer peripheral surface of the root portion 6 is inclined outward as the root portion 6 extends upward in a longitudinal cross section in this embodiment, but may be curved so as to expand outward as the root portion 6 extends upward.

The root portion 6 may be formed so that the thickness D gradually increases by inclining the outer peripheral surface outward more significantly than the inner peripheral surface in a longitudinal cross section while gradually increasing the inner diameter C1 and the outer diameter C2 as the root portion 6 extends upward.

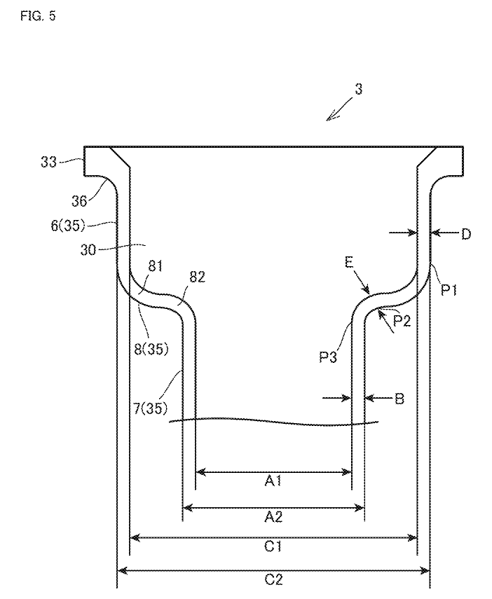

When the plate 2 is heated with the heater layer 4, a portion of the shaft portion 35 of the shaft 3, which is close to the first end portion 33 being a joint portion with the plate 2, that is, the root portion 6 has an elevated temperature and thus its thermal conductivity decreases. Reference is now made to FIG. 5. When the thickness D of the root portion 6 is as small as the thickness B of the main body portion 7, a decrease in thermal conductivity of the root portion 6 leads to an increase in temperature gradient in the root portion 6, generating large thermal stress in the root portion 6. Thus, damage may occur in the root portion 6 due to thermal stress. Meanwhile, as illustrated in FIG. 2, when the thickness D of the root portion 6 is large, heat is easily conducted through the root portion 6. Thus, as the thickness D of the root portion 6 gradually increases toward the first end portion 33 having a high temperature, the thermal conductivity of the root portion 6 gradually increases toward the first end portion 33. Accordingly, the temperature gradient in the root portion 6 is decreased, and the thermal stress generated in the root portion 6 is reduced. As a result, damage in the root portion 6 due to thermal stress can be suppressed.

Reference is made to FIG. 2. It is preferred that a corner portion 36 of the outer peripheral surface of the root portion 6, which is continuous with the first end portion 33, be formed as a radiused surface so as to be round and smooth as in this embodiment. Thermal stress is liable to concentrate at the corner portion 36. However, the concentration of thermal stress at the corner portion 36 can be suppressed by forming the corner portion 36 as a radiused surface. As a result, damage which occurs at the corner portion 36 due to thermal stress and extends therefrom can be suppressed in the root portion 6.

A thickness D1 of the root portion 6 at a boundary position (first inflection point P1) with the connecting portion 8, at which the thickness D is the smallest, may be equal to the thickness B of the main body portion 7. However, it is preferred that the thickness D1 be larger than the thickness B of the main body portion 7. In terms of enabling desirable mitigation of thermal stress generated in the root portion 6, it is preferred that the thickness D1 of the root portion 6 be 2.0 mm or more. Further, in terms of bondability of the shaft, it is preferred that the thickness D1 of the root portion 6 be 20 mm or less.

A thickness D2 of the root portion 6 at a boundary position (when the corner portion 36 is formed as a radiused surface, an inflection point P0 between the radiused surface and a lower surface or a lower end of the first end portion 33) with the first end portion 33, at which the thickness D is the largest, is larger than the thickness B of the main body portion 7. In terms of enabling desirable mitigation of thermal stress generated in the root portion 6, it is preferred that the thickness D2 of the root portion 6 be 5.0 mm or more. Further, in terms of bondability to the plate 2, it is preferred that the thickness D2 of the root portion 6 be 20 mm or less.

A ratio of the thickness D2 to the thickness D1 of the root portion 6 is not limited to a particular ratio, but is preferably 2.0 or more and 10.0 or less, more preferably 6.0 or more and 9.0 or less. As a result, bond strength of the shaft 3 and the plate 2 can be ensured while thermal stress generated in the root portion 6 can be desirably mitigated.

The connecting portion 8 includes a first portion 81 and a second portion 82. The first portion 81 is a portion on the root portion 6 side, and is, for example, curved in an arc-like manner in a longitudinal cross section. The second portion 82 is a portion on the main body portion 7 side, and is, for example, curved in an arc-like manner in a longitudinal cross section.

The first portion 81 of the connecting portion 8 is continuous from the root portion 6 and is bent so that a direction in which the shaft portion 35 of the shaft 3 extends changes from a downward direction to an inward direction. The second portion 82 of the connecting portion 8 is bent so that the direction in which the shaft portion 35 of the shaft 3 extends changes from the inward direction to the downward direction, to be continuous with the main body portion 7. The connecting portion 8 has the first inflection point P1 at a boundary position between the root portion 6 and the first portion 81, a second inflection point P2 at a boundary position between the first portion 81 and the second portion 82, and a third inflection point P3 at a boundary position between the second portion 82 and the main body portion 7.

The connecting portion 8 may be formed so that a thickness E is uniform over an entire length thereof, or may be formed so that the thickness E is not uniform and gradually increases over the entire length thereof. Alternatively, the connecting portion 8 may be formed so that a thickness E2 of the second portion 82 is uniform over an entire length of the second portion 82 while a thickness E1 of the first portion 81 gradually increases toward the root portion 6 over an entire length of the first portion 81. Further, the connecting portion 8 may be formed so that the thickness E2 of the second portion 82 gradually increases toward the first portion 81 over the entire length of the second portion 82 while the thickness E1 of the first portion 81 is uniform over the entire length of the first portion 81.

It is preferred that, in the connecting portion 8, the thickness E1 of at least the first portion 81, which is a portion on the root portion 6 side, gradually increase toward the root portion 6. When the thickness E1 of the first portion 81 which is close to the root portion 6 in the connecting portion 8 gradually increases toward the root portion 6 having a high temperature, the thermal conductivity of the first portion 81 also gradually increases toward the root portion 6. Thus, the temperature gradient in the first portion 81 can be reduced. As a result, thermal stress can be reduced from the connecting portion 8 to the root portion 6. Accordingly, damage in an area from the connecting portion 8 to the root portion 6 due to thermal stress can be suppressed. It is more preferred that the thickness E of the connecting portion 8 gradually increase toward the root portion 6 over the entire length of the connecting portion 8.

A shape of the connecting portion 8 may be various shapes as long as the connecting portion 8 can connect the root portion 6 and the main body portion 7 to each other, and is not limited to the above-mentioned shape. For example, the connecting portion 8 may include a third portion between the first portion 81 and the second portion 82. The third portion is formed so as to extend horizontally and linearly in a longitudinal cross section. Alternatively, the connecting portion 8 may be formed so that the first portion 81 extends horizontally and linearly in a longitudinal cross section. Alternatively, the connecting portion 8 may be formed so that the first portion 81 is inclined outward as the connecting portion 8 extends toward the second portion 82 in a longitudinal cross section and the second portion 82 is inclined linearly outward at an angle different from an angle at which the first portion 81 is inclined as the second portion 82 extends toward the root portion 6 in a longitudinal cross section. Alternatively, the connecting portion 8 may be formed so as to be inclined outward as the connecting portion 8 extends toward the root portion 6 between the main body portion 7 and the root portion 6.

### Description of Shaft Portion of Shaft in Second Embodiment

Reference is made to FIGS. 3 and 4. A shaft portion 35 of a shaft 3 in a second embodiment includes a root portion 9 and a main body portion 10. The root portion 9 is a portion continuous from a first end portion 33. The main body portion 10 is a portion continuous from the root portion 9 and continuous with a second end portion 34.

A shape of the main body portion 10 is the same as the shape of the main body portion 7 of the shaft 3 in the first embodiment, and thus a detailed description thereof is omitted.

The root portion 9 extends downward by a predetermined length from the first end portion 33, which is a joint portion of the shaft portion 35 of the shaft 3 with the plate 2, to be connected to the main body portion 10, and is close to the first end portion 33. A length of the root portion 9 is smaller than a length of the main body portion 10. Further, a thickness D of the root portion 9 is larger than the thickness B of the main body portion 10. The root portion 9 is a large wall thickness portion in the shaft portion 35 of the shaft 3. In this embodiment, an inner diameter C1 of the root portion 9 is equal to an inner diameter A1 of the main body portion 10. Further, an outer diameter C2 of the root portion 9 is larger than an outer diameter A2 of the main body portion 10.

The root portion 9 is formed so that a thickness D gradually increases as the root portion 9 extends upward. That is, the thickness D of the root portion 9 gradually increases over an entire length of the root portion 9 as the root portion 9 extends upward.

The root portion 9 is formed with the inner diameter C1 being constant and the outer diameter C2 gradually increasing as the root portion 9 extends upward so that the thickness D gradually increases. The root portion 9 may be formed so that the thickness D gradually increases by gradually increasing the inner diameter C1 and the outer diameter C2 as the root portion 9 extends upward with an increase in the outer diameter C2 being larger than an increase in the inner diameter C1.

An outer peripheral surface of the root portion 9 is a curved surface that is curved away from an inner peripheral surface of the root portion 9 as the outer peripheral surface extends upward in a longitudinal cross section. A curvature radius of the curved surface that forms the outer peripheral surface of the root portion 9 gradually decreases toward the first end portion 33. That is, a curvature of the outer peripheral surface of the root portion 9 increases toward the first end portion 33. Thus, the thickness D of the root portion 9 increases more significantly toward the first end portion 33.

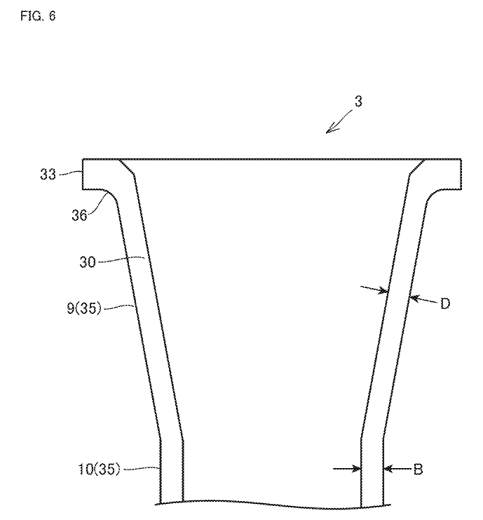

When the plate 2 is heated with the heater layer 4, a portion of the shaft portion 35 of the shaft 3, which is close to the first end portion 33 being a joint portion with the plate 2, that is, the root portion 9 has an elevated temperature and thus its thermal conductivity decreases. Reference is now made to FIG. 6. When the thickness D of the root portion 9 is as small as the thickness B of the main body portion 10, a decrease in thermal conductivity of the root portion 9 leads to an increase in temperature gradient in the root portion 9, generating large thermal stress in the root portion 9. Thus, damage may occur in the root portion 9 due to thermal stress. Meanwhile, as illustrated in FIG. 4, when the thickness D of the root portion 9 gradually increases toward the first end portion 33 having a high temperature, the thermal conductivity of the root portion 9 also gradually increases toward the first end portion 33. Accordingly, a temperature gradient in the root portion 9 decreases, reducing thermal stress generated in the root portion 9. In this case, when the thickness D of the root portion 9 more significantly increases toward the first end portion 33, the thermal conductivity of the root portion 9 also more significantly increases toward the first end portion 33. Thus, the temperature gradient in the root portion 9 can be further reduced, and hence the thermal stress generated in the root portion 9 can be effectively reduced.

It is preferred that the inner diameter C1 of the root portion 9 be constant, and the inner peripheral surface of the root portion 9 extend upward in a straight manner to be perpendicular to the second principal surface 22 of the plate 2. In this case, the thickness D of the root portion 9 can be significantly increased toward the first end portion 33, and thus thermal stress generated in the root portion 9 can be effectively reduced. The inner peripheral surface of the root portion 9 may be inclined outward as the inner peripheral surface extends upward, or may be curved so as to expand outward as the inner peripheral surface extends upward.

The curvature radius of the outer peripheral surface of the root portion 9 is not limited to a particular value. A curvature radius at a boundary position (inflection point P4) with the main body portion 10 is, for example, more than 1.0 mm and 10 mm or less. Further, a curvature radius at a boundary position (inflection point P5) with the first end portion 33 is, for example, 1.0 mm or more and less than 10 mm.

A thickness D3 of the root portion 9 at the boundary position (inflection point P4) with the main body portion 10, at which the thickness D is the smallest, is equal to the thickness B of the main body portion 10. A thickness D4 of the root portion 9 at the boundary position (inflection point P5) with the first end portion 33, at which the thickness D is the largest, is larger than the thickness B of the main body portion 10. In terms of enabling desirable mitigation of thermal stress generated in the root portion 9, it is preferred that the thickness D4 of the root portion 9 be 5.0 mm or more. Further, in terms of bondability of the shaft 3, it is preferred that the thickness D4 of the root portion 9 be 20 mm or less.

A ratio of the thickness D4 of the root portion 9 to the thickness D3 is not limited to a particular ratio, but is preferably 2.0 or more and 10.0 or less, more preferably 6.0 or more and 9.0 or less. As a result, bond strength of the shaft 3 and the plate 2 can be ensured while thermal stress generated in the root portion 9 can be desirably mitigated.

### Description of Actions and Effects of Ceramic Heater

In the ceramic heater 1 of the embodiments described above, the shaft portion 35 of the shaft 3 is formed so that its thickness is not uniform over the entire length of the shaft portion 35 and is varied for each portion. Specifically, in the shaft portion 35 of the shaft 3, the root portion 6, 9, which is close to the first end portion 33, has a high temperature when the plate 2 is heated, and the main body portion 7, 10 has a low temperature when the plate 2 is heated. The root portion 6, 9 which has a high temperature when the plate 2 is heated is formed so that a thickness of at least a portion on the first end portion 33 side gradually increases toward the first end portion 33.

Regarding the root portion 6, 9, for example, a portion which is allowed to have a high temperature equal to or higher than 400°C when the plate 2 to which the first end portion 33 is bonded is heated to 650°C and the second end portion 34 is cooled to 35°C can be specified as the root portion 6, 9. Regarding the main body portion 7, 10, for example, a portion which is allowed to have a temperature lower than 400°C when the plate 2 to which the first end portion 33 is bonded is heated to 650°C and the second end portion 34 is cooled to 35°C can be specified as the main body portion 7, 10. The root portion 6, 9 and the main body portion 7, 10 are specified through simulation analysis using a computer.

That is, a temperature of the shaft portion 35 of the shaft 3 obtained when the plate 2 is heated to 650°C and the second end portion 34 of the shaft 3 is cooled to 35°C is calculated through a simulation experiment based on simulation analysis using a computer. A temperature distribution and a temperature gradient in the shaft 3 can be obtained through simulation analysis by setting conditions including a heating temperature for the plate 2, a cooling temperature for the second end portion 34 of the shaft 3, a shape of the shaft 3, and a material (thermal conductivity) for the shaft 3. For the simulation analysis, for example, Nastran, ANSYS Mechanical, LS-DYNA, COMSOL or the like is used.

In the root portion 6, 9 which is allowed to have a high temperature, for example, equal to or higher than 400°C when the plate 2 is heated, the thermal conductivity decreases along with a rise in temperature, leading to a larger temperature gradient. As a result, large thermal stress is generated in the root portion 6, 9. Meanwhile, the thickness of at least the portion on the first end portion 33 side in the root portion 6, 9 gradually increases toward the first end portion 33 having a high temperature. As a result, heat is easily conducted through the root portion 6, 9, and the thermal conductivity of the root portion 6, 9 gradually increases toward the first end portion 33. In this manner, the temperature gradient in the root portion 6, 9 can be reduced, and hence the thermal stress generated in the root portion 6, 9 can be reduced. Thus, damage in the root portion 6, 9 due to thermal stress can be suppressed.

The main body portion 7, 10 which is allowed to have a temperature, for example, lower than 400°C when the plate 2 is heated has a small wall thickness with a thickness smaller than the thickness of the root portion 6, 9, leading to a reduction in stiffness of the main body portion 7, 10. As a result, thermal stress generated in the main body portion 7, 10 can be mitigated. Thus, damage in the main body portion 7, 10 due to thermal stress can be suppressed.

### Description of Modification Examples

The description has been given above on the ceramic heater 1 according to one embodiment of the present disclosure. It is to be understood that the embodiments disclosed herein are merely examples in all aspects and in no way intended to limit the present invention in any aspect. Thus, various modifications are possible to the embodiments of the ceramic heater according to the present disclosure without departing from the gist of the present disclosure.

The scope of the present invention is defined by the appended claims and not by the above description, and it is intended that the present invention encompasses all changes made within the scope and spirit equivalent to those of the appended claims.

1. A ceramic heater, comprising:
a plate including:
a first principal surface configured to support a wafer; and
a second principal surface positioned across a gap from the first principal surface in a thickness direction of the plate;
a resistance heating element which is built in the plate, and which is configured to generate heat through energization; and
a shaft having a tubular shape which is configured to support the plate on the second principal surface side,
wherein the shaft includes:
a first end portion which is an end portion on a side bonded to the second principal surface of the plate, and which is formed as a flange;
a second end portion which is an end portion on a side opposite to the first end portion in an axial direction of the shaft;
a root portion which is continuous from the first end portion between the first end portion and the second end portion;
a main body portion which is continuous with the second end portion between the first end portion and the second end portion, and which has an inner diameter and an outer diameter being smaller than an inner diameter and an outer diameter of the root portion; and
a connecting portion which connects the root portion and the main body portion to each other, and
wherein a thickness of at least a portion on the first end portion side in the root portion gradually increases toward the first end portion.

2. The ceramic heater according to claim 1, wherein a thickness of the main body portion is uniform over an entire length of the main body portion, and is smaller than a thickness of the root portion at a boundary position between the root portion and the connecting portion.

3. The ceramic heater according to claim 2, wherein a thickness of at least a portion on the root portion side in the connecting portion gradually increases toward the root portion.

4. The ceramic heater according to claim 1, wherein an inner peripheral surface of the root portion is perpendicular to the second principal surface of the plate.

5. The ceramic heater according to claim 2, wherein an inner peripheral surface of the root portion is perpendicular to the second principal surface of the plate.

6. The ceramic heater according to claim 3, wherein an inner peripheral surface of the root portion is perpendicular to the second principal surface of the plate.

7. A ceramic heater, comprising:
a plate including:
a first principal surface configured to support a wafer; and
a second principal surface positioned across a gap from the first principal surface in a thickness direction of the plate;
a resistance heating element which is built in the plate, and which is configured to generate heat through energization; and
a shaft having a tubular shape which is configured to support the plate on the second principal surface side,
wherein the shaft includes:
a first end portion which is an end portion on a side bonded to the second principal surface of the plate, and which is formed as a flange;
a second end portion which is an end portion on a side opposite to the first end portion in an axial direction of the shaft;
a main body portion which is continuous with the second end portion between the first end portion and the second end portion; and
a root portion which is continuous from the first end portion between the first end portion and the second end portion, and which connects the first end portion and the main body portion to each other,
wherein a thickness of the root portion gradually increases toward the first end portion, and
wherein an outer peripheral surface of the root portion is a curved surface being curved away from an inner peripheral surface of the root portion as the root portion extends toward the first end portion, and a curvature radius of the curved surface gradually decreases toward the first end portion.

8. The ceramic heater according to claim 7, wherein a thickness of the main body portion is uniform over an entire length of the main body portion.

9. The ceramic heater according to claim 7, wherein an inner peripheral surface of the root portion is perpendicular to the second principal surface of the plate.

10. The ceramic heater according to claim 8, wherein an inner peripheral surface of the root portion is perpendicular to the second principal surface of the plate.

11. A ceramic heater, comprising:
a plate including:
a first principal surface configured to support a wafer; and
a second principal surface positioned across a gap from the first principal surface in a thickness direction of the plate;
a resistance heating element which is built in the plate, and which is configured to generate heat through energization; and
a shaft having a tubular shape which is configured to support the plate on the second principal surface side,
wherein the shaft includes:
a first end portion which is an end portion on a side bonded to the second principal surface of the plate, and which is formed as a flange;
a second end portion which is an end portion on a side opposite to the first end portion in an axial direction of the shaft;
a root portion which is continuous from the first end portion between the first end portion and the second end portion, and which is allowed to have a high temperature equal to or higher than 400°C when the plate is heated to 650°C and the second end portion is cooled to 35°C; and
a main body portion which is continuous with the second end portion between the first end portion and the second end portion, and which is allowed to have a temperature lower than 400°C when the plate is heated to 650°C and the second end portion is cooled to 35°C, and
wherein a thickness of at least a portion on the first end portion side in the root portion gradually increases toward the first end portion.

12. The ceramic heater according to claim 1, wherein a ratio of a thickness of the root portion at an end on the first end portion side to a thickness of the root portion at an end on the main body portion side is 2.0 or more and 10.0 or less.

13. The ceramic heater according to claim 11, wherein a ratio of a thickness of the root portion at an end on the first end portion side to a thickness of the root portion at an end on the main body portion side is 2.0 or more and 10.0 or less.

14. The ceramic heater according to claim 1, wherein the shaft is formed of a material containing Mg and Al.

15. The ceramic heater according to claim 7, wherein the shaft is formed of a material containing Mg and Al.

16. The ceramic heater according to claim 11, wherein the shaft is formed of a material containing Mg and Al.
